(19) United States
(12) Patent Application Publication
(10) Pub. No.: US 2008/0072821 A1
(43) Pub. Date: Mar. 27, 2008

(54) SMALL VOLUME SYMMETRIC FLOW SINGLE WAFER ALD APPARATUS

(76) Inventors: Jeremic J. Dalton, San Jose, CA (US); Martin Dauelsberg, Aachen (DE); Kenneth Doering, San Jose, CA (US); M. Ziaul Karim, San Jose, CA (US); Thomas E. Seidel, Sunnyvale, CA (US); Gerhard K. Strauch, Aachen (DE)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 11/780,698

(22) Filed: Jul. 20, 2007

Related U.S. Application Data
(60) Provisional application No. 60/820,042, filed on Jul. 21, 2006.

(51) Int. Cl. C23C 16/00

(52) U.S. Cl. 118/715

(57) ABSTRACT

A reaction chamber apparatus includes a vertically movable heater-susceptor with an attached annular attached flow ring that performs as a gas conduit. The outlet port of the flow ring extends below the bottom of a wafer transport slot valve when the susceptor is in its process (higher) position, while the gas conduit formed by the flow ring has an external surface at its edge that isolates the outer space of the reactor above the wafer from the confined reaction space. In some cases, the outer edge of the gas conduit is in proximity to a ring attached to the reactor lid and, together, the ring and conduit act as a tongue-in-groove (TIG) configuration. In some cases, the TIG design may have a staircase contour, thereby limiting diffusion-backflow of downstream gases to the outer space of the reactor.

### RELATED APPLICATIONS

This application is a non-provisional of, claims priority to and incorporates by reference U.S. Provisional Patent Application 60/820,042, filed 21 Jul. 2006; and is also related to and incorporates by reference German patent application DE 102005056326.6 by Strauch and Seidel, filed 22 Nov. 2005; U.S. patent application Ser. No. 11/224,767 by Puchacz et al., filed 12 Sep. 2005, which is a non-provisional of, claims priority to and incorporates by reference U.S. Provisional Patent Application 60/609,598, filed 13 Sep. 2004; each of which is assigned to the assignee of the present invention.

### FIELD OF THE INVENTION

The present invention relates to a small volume symmetric-flow Atomic Layer Deposition (ALD) apparatus that improves ALD cycle times by minimizing the reaction space volume while maintaining symmetry of gas flow related to off-axis wafer transport slot valves and/or off-axis downstream pumping conduits.

### BACKGROUND

ALD reactors may have a variety of design configurations. Conventional single wafer ALD reactor configurations include a cross-flow design (Suntola), wherein sequential chemical precursor exposures (pulses) and removals (purges) of injected gases flow substantially horizontally across the wafer surface and are pumped out in the horizontal direction as well. Wafer transport may be carried out in the same horizontal plane, at right angles to the gas flow direction. The term “traveling wave” has been used to refer to the movement of the time-dependent precursor pulses from injection orifice(s) to pump orifice(s). See, e.g., T. Suntola, “Atomic Layer Epitaxy,” in Handbook of Crystal Growth 3, Huerle ed., Ch. 14, pp. 601 et seq. (1994).

In so-called “pure” ALD processes, the first precursor is completely removed from the reaction space before the second precursor is introduced. See, S. M. Bedair, “Atomic layer epitaxy deposition processes,” J. Vac. Sci. Tech. B12 (1), January/February, pp. 179 et seq. (1994). However, as wafers scale to larger sizes, e.g., 300 mm and 450 mm, and as cycle times are pushed to lower limits, undesirable parasitic chemical vapor deposition (CVD) takes place at the edge of the wafer in the direction of the traveling wave. The parasitic CVD is due to undesirable chemical reactions from the simultaneous co-existence, in time and space, of the remnant precursor in the dispersion trailing tail of the first precursor and the onset of the second precursor. Parasitic CVD is undesirable in many ALD processes because it can lead to an increase in the within-wafer film thickness non-uniformity, reduced step coverage and uncontrolled changes in other film properties across the wafer surface. To avoid this parasitic CVD, precursor removal is used between pulses. Often, long removal times are needed. In the horizontal single wafer architecture, to avoid this parasitic CVD the concentration of the trailing edge of the first precursor pulse must be reduced to trace levels, for example an arbitrary figure of less than approximately 1% of the first precursor's peak value. See, e.g., U.S. Pat. No. 6,015,590 to Suntola.

Since ALD is a self-limiting process, it may be argued that the direction and symmetry of flow of the precursors does not matter because if enough time is used for the precursor removal periods—commonly referred to as the “purge period”—there will be no significant CVD. However, in the pursuit of high deposition rates (thickness/unit time or low cycle times), as purge times are pushed to the lowest possible times for value in commercial manufacturing, the symmetry of the flow becomes important. This is because, when operating at the practical limits of pulse and purge times, the flow symmetry will largely govern the deposition thickness symmetry on the wafer.

Alternative single wafer designs use injected precursor gases from axi-centric and axi-symmetric vertical gas distribution modules (GDM) (e.g., using an axi-centric orifice(s) or showerhead). An example of such a system 100 is shown in FIG. 1. Here, precursors A and B, 110 and 112 respectively, and/or a purge gas 118 are introduced (e.g., under control of valves 120 and 122 in the case of the precursors) via vertical injection into a reaction chamber 114 through a GDM 116. This arrangement allows for radial gas flow over a wafer 124, which is supported in chamber 114 by a heater-susceptor 126, followed by vertical pumping using pump 128. In this case, the dispersion tails are limited to overlap across the radius of the wafer (½ the value of the diameter); advantageous in the case of high back diffusion. Today, many commercial single wafer ALD reactors use this form of vertical precursor injection with radial flow, followed by vertical pumping. See e.g., U.S. Pat. No. 7,138,336 to Lee et al.

The idealized vertical injection/radial flow/vertical downstream pumping design discussed with reference to FIG. 1 allows for rapid pumping (e.g., pumping at all azmuthal angles) and removal of unused and by-product gases, while providing symmetry of flow at the wafer edges. However, often the reaction space volume 130 and downstream volumes 132 may be relatively large for optimized ALD operation. Further, in actual commercial ALD (or CVD) systems, the pump cannot always be placed symmetrically with respect to the gas flow arrangement and the wafers must be introduced into and removed from the reaction chamber through an access slot valve assembly (not shown in FIG. 1). These requirements for wafer loading/unloading and asymmetric pumping configurations disrupt the symmetry in the otherwise symmetric design illustrated in FIG. 1.

FIGS. 2a and 2b help to illustrate this latter point. FIG. 2a is a partial cut-away top view of a reactor system 200 similar to that shown in FIG. 1, while FIG. 2b is a side view thereof. In this arrangement, wafers 224 are introduced into the reaction chamber from a wafer handling mechanism 210 through a rectangular slot valve 204 at a particular azimuthal angle and range (θ₁ and Δθ₁) that is on the radius or outer surface of the reaction chamber in proximity to the walls of the reactor. This slot valve and its rectangular passage into the chamber breaks the symmetry of radial gas flow, as shown schematically in FIG. 2b.

Furthermore, the downstream exhaust pump 228 is commonly set at an azimuthal angle and range, θ₂ and Δθ₂, where θ₂ is in general not necessarily the same as θ₁. While this arrangement accommodates on-axis mechanical drive support hardware to achieve a vertically movable susceptor 126, together these asymmetries can lead to the formation of recirculation pockets, stagnation zones (206, 208) and/or pumping azimuthal non-uniformities. For example, if the residual precursor from the first precursor's flow are pumped or swept in a non-uniform azimuthal flow from the wafer, an additional mechanism is present for parasitic CVD to occur non-symmetrically or non-uniformly towards one azmuthal direction of the wafer. In this case, the onset of parasitic CVD occurs non-symmetrically and prematurely over particular azimuthal directions or angle(s) due to recirculations, stagnations and/or pumping effects.

The desirability of a small reaction space volume (the space above the wafer between the wafer and the precursor injection component (e.g., a showerhead)), is known in the art. See, e.g., M. Ritala and M. Leskela, “Atomic Layer Deposition” in Handbook of Thin Film Materials, H. Nalwa, ed., vol. 1, Ch. 2, pp. 103 et seq. (2002). The ALD reaction space volume should be minimized for reduced precursor removal time, reduced residence time (PV/flow) and therefore reduced ALD cycle time. With a vertically movable susceptor design (see, e.g., U.S. Pat. No. 5,855,675 of Doering, et. al., assigned to the assignee of the present invention and incorporated herein by reference), the distance between the wafer plane and the gas distribution orifices (showerhead) in the reactor lid may be optimized for uniformity of flow and residence time; that is, the volume of the reaction space may be minimized within the constraint of locally uniform exposures. Additionally, the reaction space may include the annulus region between the susceptor edge and the reactor's upper inner wall, which is parasitic reaction space volume.

While the broken flow symmetry due to azimuthal placement of the wafer slot valve and wafer passage was substantially restored by using a vertically movable susceptor/heater configured so that when the wafer and its heater/susceptor were in the process position the wafer was above the wafer slot valve, this approach was still limited with respect to fine control of symmetric flow. For example, downstream gases may still form stagnation regions and eddies in the pocket associated with the wafer slot valve below the wafer plane when the susceptor is in its process position. Hence, what is needed is a reactor design that provides a minimal reaction space volume and improved symmetric flow, while maintaining the ability to work with conventional wafer (slot) transport mechanisms. The current invention provides a solution to these requirements, resulting in a small, confined volume with symmetric flow resulting in a high throughput, high performance (HP) single wafer reactor.

### SUMMARY OF THE INVENTION

In one embodiment of the invention, a reaction chamber apparatus includes a vertically movable heater-susceptor, where the heater-susceptor is connected to an annular attached flow ring that performs as a gas conduit, with an outlet port of the flow ring extending below the bottom of a wafer transport slot valve when the susceptor is in the process (higher) position.

A further embodiment of the invention provides a reaction chamber apparatus containing a heater-susceptor connected to an annular attached flow ring conduit at the perimeter of the susceptor, the conduit having an external surface at its edge that isolates the outer space of the reactor above the wafer and below the wafer to the bottom of the flow ring from the confined reaction space when the heater-susceptor is in its process (higher) position with respect to its loading position.

In still another embodiment, the present invention provides a reaction chamber apparatus containing a heater-susceptor connected to an annular attached flow ring conduit at the perimeter of the susceptor, the conduit having an external surface at its edge that isolates the outer space of the reactor above the wafer from the confined reaction space when the heater-susceptor is in its process (higher) position with respect to the loading position, the outer edge being placed in proximity with an annular ring attached to the reactor lid and together the ring and conduit outer member acting together as a tongue-in-groove (TIG) configuration. In some cases, the TIG design may have a staircase (SC) contour, thereby limiting diffusion-backflow of downstream gases to the outer space of the reactor.

A further embodiment of the present invention provides a reaction chamber apparatus having a vertically movable susceptor (VMS) with respect to its loading (lower) position, said susceptor being connected to an annular attached flow ring (AFR) (or deep flow ring (DFR)) conduit at the perimeter of the susceptor, said annular AFR passing reaction gas effluent to a downstream pump orifice that is off-axis with respect to the axi-centric center of the reaction chamber. In some cases a downstream baffle may be placed between the lower orifice of the annular AFR and the downstream pump to attain symmetric gas flow at the edges of the wafer in the upstream wafer plane.

Still a further embodiment of the invention provides a TIG chamber configuration as described above and having a pump connected to remove gas streams from the reaction space, the AFR conduit and the lower chamber leading to the pump. A gas injection orifice that allows for by-passing the reaction space and the AFR conduit is placed such that gas injected through said orifice enters into the stream leading to the pump below the output orifice of the AFR. Hence, the orifice provides for directly injecting a gas into the pumping conduit leading directly to the input of the pump, without further restrictor(s) between the AFR output orifice and the pump input orifice, periodically during ALD cycling. In some cases the gas so injected may be injected at azmuthal points to achieve uniform exposure and uniform residence time. Also, the orifice of the AFR may have restrictors in the form of holes at the plane of its orifice, and the holes may be designed differently in different azmuthal directions to induce symmetric flow at the wafer plane. The TIG design may be such that the inner edge of the TIC lid element is curved to remove dead space in the reaction space.

The HP ALD design described herein may be further utilized in a “multi-single wafer” (MSW) reactor system as described for example in the above-referenced patent applications by Puchacz, et. al. and Strauch & Seidel. In that case, several (e.g., four) substantially independent HP reactors may be placed in a common vacuum housing system. In the application by Strauch & Seidel there is the added requirement of small gas flow (mostly via back-flow by diffusion as apposed to convective flow) between the otherwise substantially independently operating reactors placed within the same master vacuum housing.

Thus the HP ALD system described herein, is quantified with respect to the confined reaction space volume (minimized and optimized), with minimal re-circulations, symmetric flow, and small gas reactant transport outside the HP reaction zones. See FIG. 3 which illustrates the relative orientations of the DFR, wafer slot valve position and the orifice of the DFR below the slot valve. This system may be used for a single wafer deposition, with a single carrier for depositions on multiple smaller wafers placed on the carrier, or with multiple substrates not on carriers. Importantly, in the context of the use of this confined design as a single, stand alone wafer reactor, the reactants are beneficially shielded from deposition on the inner walls of the reactor chamber, thus providing an advance in maintenance benefits for single wafer reactors.

### BRIEF DESCRIPTION OF THE DRAWINGS

The present invention is illustrated by way of example, and not imitation, in the figures of the accompanying drawings, in which:

FIG. 1 illustrates an ALD reactor with vertical precursor injection and combined radial/vertical flow pumping;

FIGS. 2a and 2b illustrate the effects of a slot valve and off-axis downstream pump in breaking the symmetry of radial gas flow within an ALD apparatus;

FIG. 3 illustrates relative orientations of a deep flow ring (DFR), wafer slot valve position and the orifice of the DFR below the slot valve within an ALD apparatus configured in accordance with an embodiment of the present invention;

FIGS. 4a-4d are detailed views of ALD apparatus configured in accordance with various embodiments of the present invention, showing alternative designs for lid ring-flow ring interfaces and contoured fillets to remove dead zones in corners of a reaction chamber;

FIG. 5 illustrates the use of a downstream baffle to improve symmetry of an upstream flow in an ALD apparatus in accordance with an embodiment of the present invention; and

FIG. 6 is a further illustration of an embodiment of the present invention, showing the relationship between the deep flow ring and the wafer slot valve when the susceptor is in the processing position.

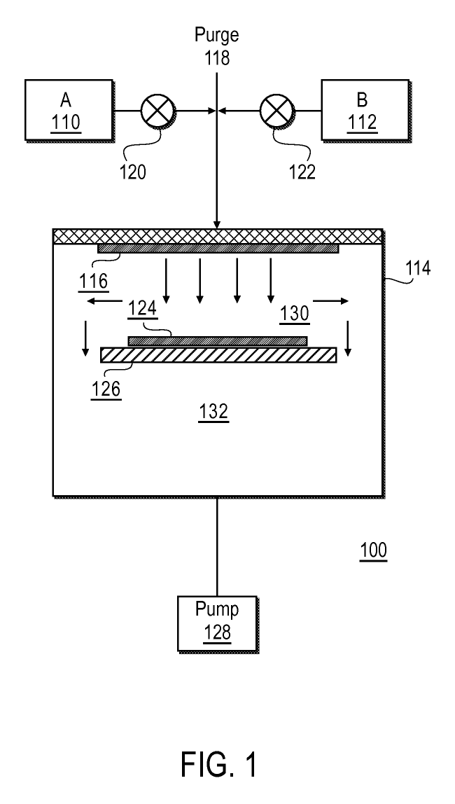

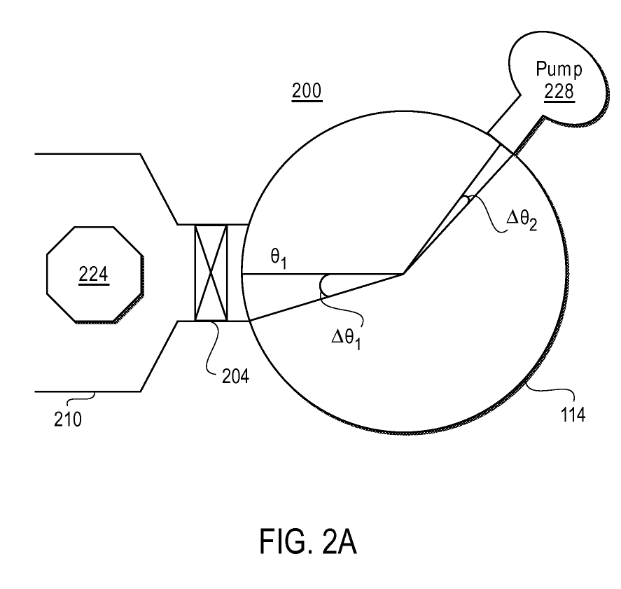

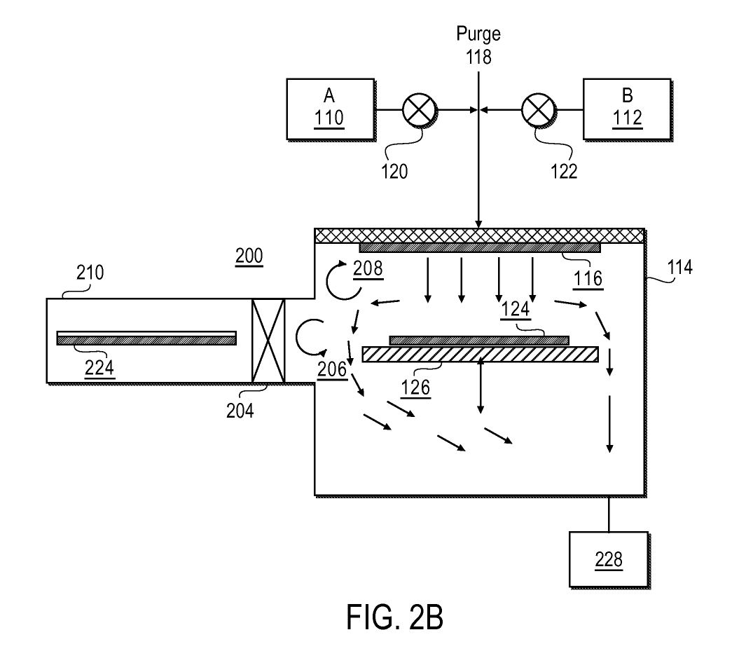

### DETAILED DESCRIPTION

Described herein is a small volume symmetric flow (SVSF) apparatus defined for a minimal ALD reaction space volume with axi-symmetric flow with minimal chemical transport to the reactor walls. The description includes the reactor design and its functionality, as well as a discussion of the combined effects of small volume for the reaction space, generalized design for isolation of the reaction space from the reactor walls without stagnations and re-circulations, the minimization of gas expansion volume below the wafer plane, and a potential for time-phased multilevel choked downstream pump configuration suitably designed in all cases to achieve flow symmetry in the case of off-axis pumping conduits with maintainability and assembly features.

A consideration for the design of the small volume axi-symmetric flow ALD reactor is the requirement to deliver gas precursors rapidly and substantially uniformly across the semiconductor wafer or wafers or work piece or work pieces with high topology features. To achieve minimal exposure times and efficient precursor use, we desire chemical precursors to be brought to high aspect features in the center and the edge of the wafer in nearly the same timeframe, and with nearly the same concentration.

The benefit of same time exposure is to achieve efficient conformal coatings over the wafer area. The within-wafer non-uniformity of high topology features will be optimally small, while simultaneously using a minimal amount of precursor. To understand this, we refer to the theory for coating “holes” with high aspect ratios. R. Gordon, et al., “A Kinetic Model for Step Coverage by Atomic layer Deposition in Narrow Holes or Trenches,” Chem. Vap. Deposition, 9, No. 2, pp. 73 et seq. (2003). The exposure of a single ALD precursor proceeds by gas diffusion transport to the interior surfaces from the top down to the bottom of the hole. Holes placed near the location on the wafer having precursor arrival will coat first near the top and later coat at the bottom of the hole with a single pulse of suitably sufficient dosage. Holes farther away from the position of first precursor arrival to the wafer will coat to saturation at the bottom of their features at a later time. Reactors with distributed vertical injection are better suited to meet this condition efficiently, while reactors with horizontal injection perform poorly in this regard. In order to achieve an efficient coating, it is desirable to use a suitably designed showerhead or gas distribution manifold (GDM), where the gases are dispensed as simultaneously as possible over the entire wafer surface.

An optimal ALD system includes consideration of a rapid and efficient chemical precursor delivery into the GDM, and a GDM that, in turn, provides rapid precursor flow into the reaction space (see, e.g., U.S. patent application Ser. No. 11/278,700 of Dalton et al., filed 5 Apr. 2006, assigned to the assignee of the present invention and incorporated herein by reference). The detailed design of showerheads of uniform injection and low residence times (as well as chemical precursor source vaporizers of high partial pressure) are separate considerations from the design of the reactor itself, but must be optimized and integrated with best practices to obtain a fully competitive system.

In summary, a high performance system includes a chemical precursor source capable of rapidly delivering high partial pressures of precursor vapors by way of the GDM and optimized reactor chamber design. For the purposes of this disclosure, we consider the chemical source/delivery, GDM and reactor as modular with respect to each other and separately optimized. However, as mentioned above, for efficient uniform coatings of high topology features, one advantageously uses axi-symmetric exposure at the center and edge of the wafer at nearly the same time and a reactor design that is axi-symmetric with respect to flow at the edge of the wafer.

In considering the merits of axi-symmetric flow, we discuss the benefits of symmetric flow during wafer exposure as well as the removal of the reactants and byproducts from the reaction chamber. The importance of removing precursors with azmuthal symmetry is related to the minimization of the onset of parasitic CVD at all azmuthal points located either near the center circular zone of the wafer or around the edge, in a donut-like or toroidal zone, of the wafer. The signature of parasitic CVD near the center will occur if the upstream remnants of the “A” precursor are dominant at the time that the “B” precursor pulse is switched on. In such cases, the GDM region has not been adequately cleared. Conversely, the signature of parasitic CVD near the edge of the wafer will occur if the downstream remnants of the “A” precursor are dominant when the leading edge of the “B” precursor arrives near the edge of the wafer. In these cases, the region down-stream from the wafer has not cleared. Additionally, whether having azmuthal symmetry or not, if the design permits flows to re-circulate in the pocket regions associated with the wafer slot valve, or stagnate in unnecessary dead-space corners, then eddies can result and precursor remnants may exist in the precursor removal/purge periods and give rise to parasitic CVD

Thus, the starting constraints of the design challenges are:
a. The injection flow favors a GDM of axi-symmetric geometry with respect to the target work piece. For example, this may be a circular GDM with its center aligning (at least when in the processing position) with the center of a circular wafer (or other work piece) or a group of circular wafers (or work pieces) upon which depositions will take place.
b. The wafers are placed on the heater-susceptor using horizontal motion by robotic handling through a rectangular slot valve.
c. The pumping port leading to the downstream pump may be off-axis with respect to the central wafer axis.
d. The reaction space (the volume between the showerhead and the wafer surface) is to be minimized.
e. The downstream volumes are to be minimized, minimizing gas expansion that would lead to long purge times, and the use of (unnecessary) downstream constrictions eliminated, maximizing the conductance from the reaction space to the downstream pump.
f. A multilevel flow may be implemented without the use of limiting constriction on the downstream side of the point of introduction of a gas inlet to modify the effective pumping speed of the downstream pump to improve the ALD reaction efficiency on the wafer.

The ALD cycle time (CT) consists of exposure of a first precursor, followed by removal (or “purge”) of unused portions of the first precursor and first precursor's reaction by-products, followed by exposure of a second precursor and removal of the unused portions of the second precursor and second precursor's reaction by-products. The sum of these four cycle time elements are the ALD CT.

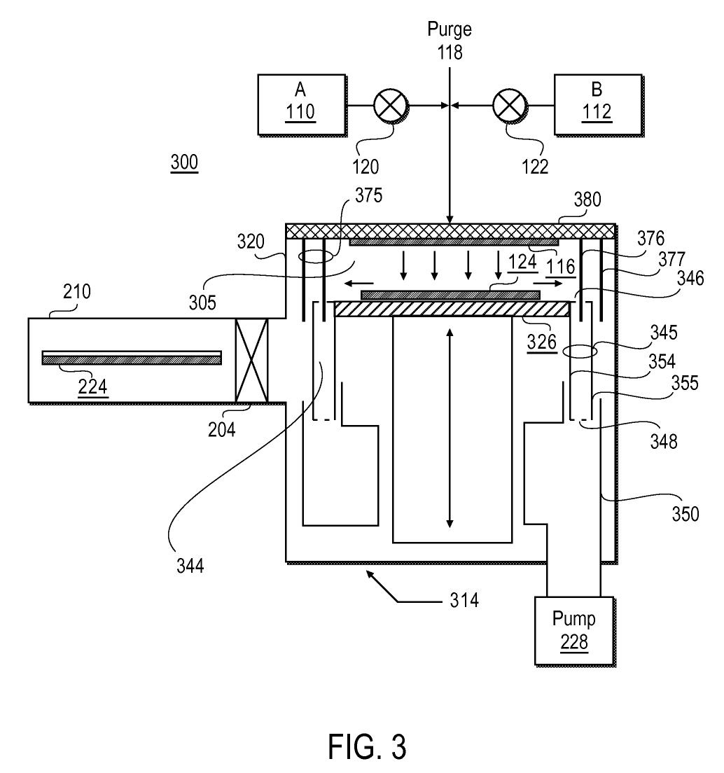

In the present invention, to minimize the reaction space volume (305 in FIG. 3), a confined flow path is defined by attaching a guiding annular pumping conduit 344 to the edge of a vertically movable heater-susceptor 326. This design places and confines the flow path as close to the wafer as possible and takes the form of a flow ring 345 that is mechanically attached to the heater-susceptor 326. Precursor removal periods are greatly reduced and cycle time (CT) is improved (see, e.g., J. Dalton et. al., “High Performance ALD Reactor for Advanced Applications,” presented at ALD2006 International Conference of the American Vacuum Society, Seoul Korea, Jul. 24-26, 2006) by using an annular conduit flow ring that is attached to a movable vertical susceptor (see, e.g., the Doering reference cited above).

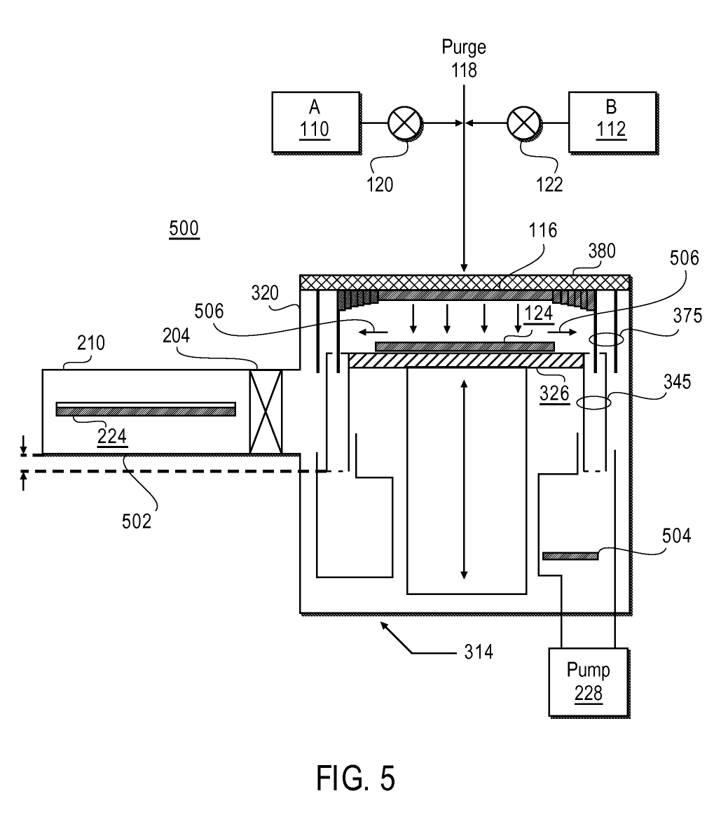

The flow ring 345 (with inner surface element 354 and outer surface element 355) has a conduit with an input orifice 346 at nominally the same height as the susceptor. The lower orifice 348 of the flow ring is below or substantially below the lower edge 502 of the slot valve 204 when the wafer (i.e., the susceptor) is in the processing position (see, e.g., FIG. 5). This constraint provides excellent convective flow isolation from the slot valve and improves flow symmetry at the edge of the wafer and just downstream of the wafer surface. The deep flow ring (DFR) 345 then is suitably defined. The outer edge of the DFR is placed close to the downstream reactor chamber wall 350, minimizing diffusive back flow to the slot valve 204 and upper outer reactor wall surfaces 320.

When the vertically movable susceptor 326 with the deep flow ring 345 is elevated into its “up” or processing position, the outer surface element 355 of the DFR 345 is placed in close proximity and overlapped with respect to a bottom of an inner surface element 376 of a “lid-ring” 375 (made up of inner element 376 and an outer element 377) that is attached to inside of the lid 380 of the reactor 314. The basic design is illustrated in FIG. 3. The inner surface element 376 of the lid ring 375 and the outer surface element 355 of the flow ring 345 define the confining surfaces for the reactant flows and provide confinement of the reaction space. Thus, in one embodiment, the DFR at the perimeter of the heater-susceptor isolates an outer space of the reactor both above and below a wafer position when the heater-susceptor is in a processing position.

By iterative simulation, it has been found that (still) some small amount of reactants back-diffuse upstream within the conduit of the flow ring and the intended isolated region outside of the lid ring. This results in unwanted deposits on the reactor wall and, in the case of, for example, a multi-single-wafer reactor (e.g., as described by Puchacz et al. in the above-cited U.S. patent application Ser. No. 11/224,767), results in excessive diffusive cross-talk between intended independent reactors.

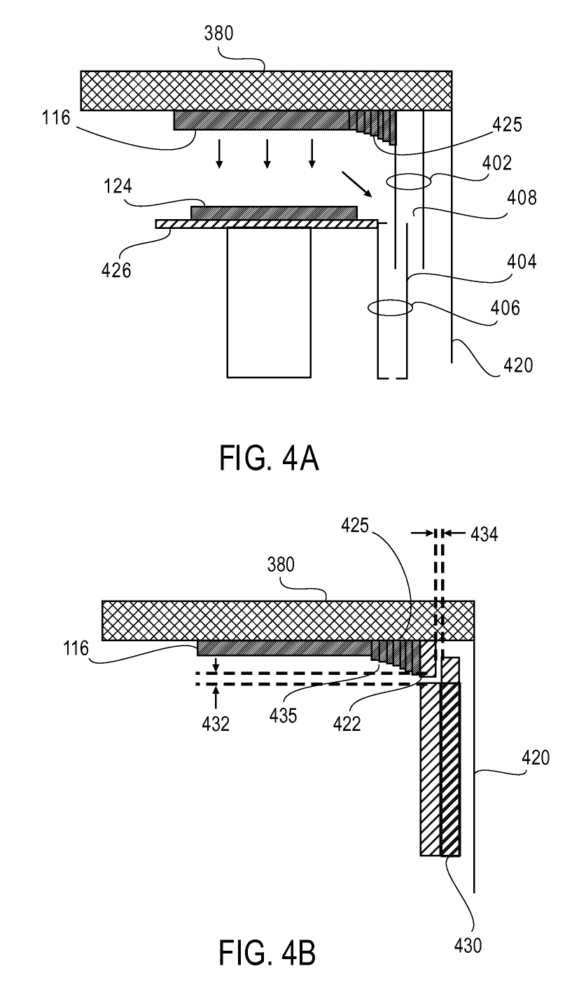

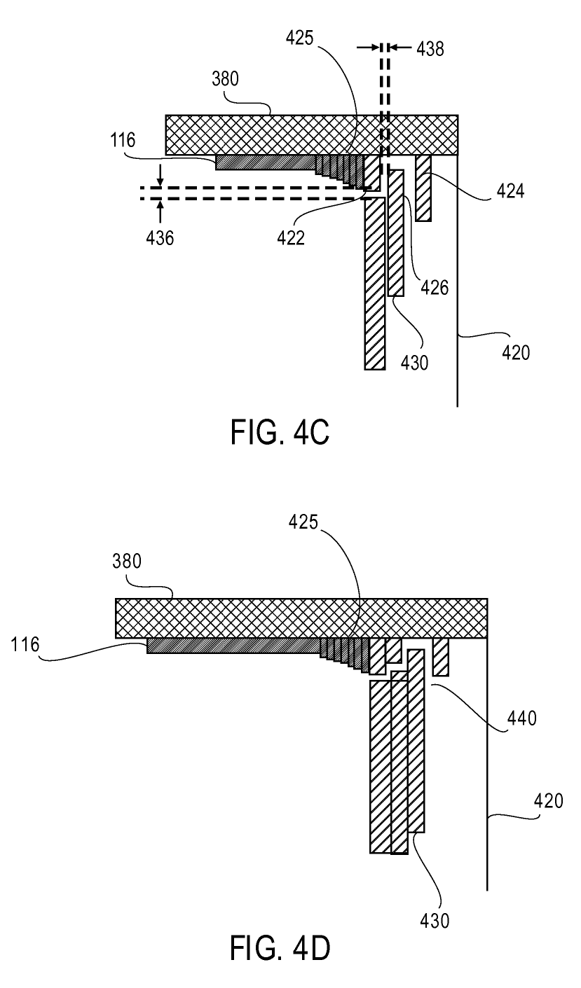

Hence, referring now to FIG. 4a, one embodiment of the present invention (similar to system 300 shown in FIG. 3) configures reactor lid ring(s) 402 with a recess 408 that permits insertion of an outer surface 404 of a flow ring 406 into the recess when the susceptor 426 is positioned “up” for processing. The result is a “tongue in groove” (TIG) design, as illustrated. By Computational Fluid Dynamic (CFD) simulation, this TIG design produces (with minimal mechanical dimensions that are controllable in practice) a back-diffused chemical concentration yielding about a 100-fold level of reduction in the steady state deposition rate on the outer reactor wall 420 relative to the wafer deposition rate.

As shown in FIG. 4b, an alternative, “staircase” design may also be used to isolate the reaction space 435 from the external reactor wall 420. In this case, the flow ring resembles a staircase arrangement engaged with only a single lid ring 422; yet, there is an equivalent TIG design associated with this single lid ring when one considers the effect of the outer wall 420 of the reactor. Of course, this design would require tight tolerances at the staircase-to-ring spacings 432 and 434 to achieve good isolation performance.

Still further reduction of diffusive back-flow can be obtained by using a TIG design with matched staircase surface contours on the flow ring and lid ring, as shown in FIG. 4c. Here, an inner lid ring 422 and an outer lid ring 424 provide the “groove” for “tongue” portion 426 of the outer wall 430 of the staircase-like flow ring to reside within when the susceptor is in its process position. Supporting simulations for the back-diffusion for this staircase-TIG design indicate up to a 10,000-fold reduction in back-diffusion relative to the steady state wafer deposition rate, depending on the values of practical spacing(s) 436 and 438 in the staircase. This staircase-TIG design also addresses mechanical thermal expansion issues (dominated by radial expansion) that may otherwise make the tolerances required in a TIG design difficult to practically maintain.

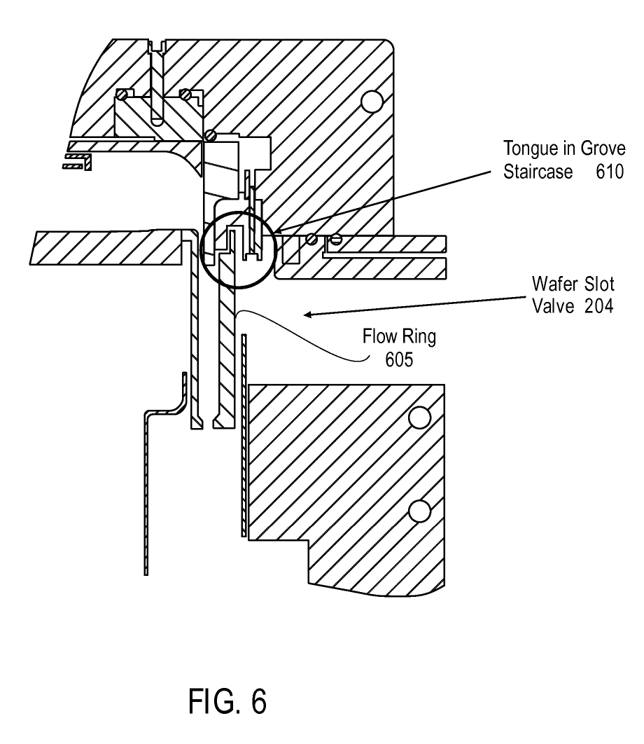

FIG. 6 illustrates another example of the use of this staircase-TIG design 610 and shows the relation of the flow ring 605 and wafer slot valve 204 to one another when the susceptor is in its up or processing position.

Returning now to FIG. 4d, also contemplated within the scope of the invention are higher-order multiple-staircase designs, such as the 3-step staircase 440 illustrated in this drawing. Such a configuration can reduce the diffusive transport to the reactor walls 420 even further than as for the one- or two-step staircase designs discussed above. Thus, there is a hierarchy of performance for attached flow ring designs that can lead to a “generalized staircase” design, with multiple stair steps combined with TIG-like elements.

Importantly, if the DFR were not defined as extending deeper than the slot valve, then the re-circulations and isolation with respect to the slot valve would be poor. These poor alternative results imply a certain uniqueness to the attached extended depth annular DFR combined with a staircase-TIG design.

CFD simulations indicate that the design as shown in FIG. 3 has a non-symmetric flow of approximately 10% due to the off-axis pump. As shown in FIG. 5, this off-axis pump location for a system 500 can be engineered by placement of a downstream azimuthal baffle 504 covering an azimuthal angle of approximately 10 to 90 degrees, centered to balance the azimuthal flows 506 at the edge of the wafer.

The above-described ALD system can be operated using a multilevel flow process, such as that described in U.S. patent application Ser. No. 10/791,030 of Liu et al., assigned to the assignee of the present invention and incorporated herein by reference (which application also discusses a bi-level flow system proposed by Sneh in WO 03/062490), wherein for the assignee's case there is no downstream restrictor. Hence, embodiments of the invention may provide a TIG chamber configuration as described above and having a pump connected to remove gas streams from the reaction space, the DFR conduit and the lower chamber leading to the pump. A gas injection orifice that allows for by-passing the reaction space and the DFR conduit is placed such that gas injected through said orifice enters into the stream leading to the pump below the output orifice of the DFR. The orifice thus provides for directly injecting a gas into the pumping conduit leading directly to the input of the pump, without further restrictor(s) between the DFR output orifice and the pump input orifice, periodically during ALD cycling. In some cases the gas so injected may be injected at azimuthal points to achieve uniform exposure and uniform residence time. Also, the orifice of the DFR may have restrictors in the form of holes at the plane of its orifice, and the holes may be designed differently in different azimuthal directions to induce symmetric flow at the wafer plane.

Thus, a small volume symmetric flow apparatus defined for a minimal ALD reaction space volume with axi-symmetric flow with minimal chemical transport to the reactor walls has been described. Although discussed with reference to certain illustrated embodiments, however, the present invention is not limited to these embodiments. For example, as shown in FIGS. 4a-4d, the various staircase and/or TIG designs may be such that the inner edge 425 of the TIG lid ring is curved or filleted to remove dead space in the reaction space. Such fillets may or may not be attached to the GDM. Further, maintenance features of the present designs are also favorable. ALD deposits on the inside walls of the deep flow ring will ultimately require maintenance. This is carried out by a maintenance procedure using lid-access to the heater-susceptor, followed by manual removal and replacement of the used DFR component. The used deep flow ring may then itself be cleaned and reused. Thus, the present invention should only be measured in terms of the claims following this description. Further, the simulation methodologies and results, along with supporting data, set forth in Appendix A of the above-cited U.S. Provisional Patent Application 60/820,042 are incorporated herein by reference.

What is claimed is:

1. A reaction chamber apparatus comprising a vertically movable heater-susceptor coupled to an annular flow ring configured as a gas conduit and having an outlet port extending below a bottom of a wafer transport slot valve of the reaction chamber apparatus when the heater-susceptor is in a processing position.

2. A reaction chamber apparatus comprising a heater-susceptor coupled to an annular flow ring conduit at a perimeter of the heater-susceptor, the flow ring conduit having an external surface at its edge, the external surface configured to isolate an outer space of the reactor both above and below a wafer position when the heater-susceptor is in a processing position.

3. A reaction chamber apparatus comprising a heater-susceptor coupled to an annular flow ring conduit at a perimeter of the heater-susceptor, the annular flow ring defined by inner and outer members and configured to isolate an outer space of the reaction chamber above a wafer position from a confined reaction space of the reaction chamber when the heater-susceptor is in a processing position, in which instance the outer member of the annular flow ring is in proximity with a second annular ring attached to a lid of the reactor, the outer member of the annular flow ring and the second annular ring forming a tongue-in-groove (TIG) configuration.

4. The reaction chamber apparatus of claim 3, wherein the TIG configuration comprises a staircase contour, operable to limit diffusion-backflow of downstream gases to an outer space of the reaction chamber apparatus.

5. The reaction chamber apparatus of claim 3, further comprising a pump coupled to remove gas streams from the reaction chamber, the annular flow ring conduit and a lower chamber leading to the pump.

6. The reaction chamber apparatus of claim 5, further comprising a gas injection orifice coupled to permit by-passing of the reaction chamber and the flow ring conduit such that gas injected through said orifice enters into a stream leading to the pump below an output orifice of the flow ring.

7. The reaction chamber apparatus of claim 6, wherein the gas injection orifice is configured such that gas is injected at azimuthal points.

8. The reaction chamber apparatus of claims 6, wherein the flow ring orifice includes restrictors in the form of holes at a plane of the orifice.

9. The reaction chamber apparatus of claim 8, wherein the holes are configured differently in different azimuthal directions.

10. The reaction chamber apparatus of claim 3, wherein an inner edge of the lid is curved.

11. A reaction chamber apparatus comprising a vertically movable susceptor coupled to an annular flow ring conduit at a perimeter of the susceptor, said annular flow ring conduit configured to pass reaction gas effluent to a downstream pump that is located off-axis with respect to an axi-centric center of the reaction chamber.

12. The reaction chamber apparatus of claim 11, further comprising a downstream baffle located between a lower orifice of the annular flow ring and the downstream pump.

13. The reaction chamber apparatus of claim 11, further comprising a second annular ring attached to a lid of the reaction chamber apparatus, the second annular ring being in proximity to an outer member of the annular flow ring conduit when the vertically movable susceptor is in a process position, the second annular ring and the outer member of the annular flow ring conduit forming a tongue-in-groove (TIG) configuration.

14. The reaction chamber apparatus of claim 13, wherein the second annular ring is an inner lid ring and further comprising an outer lid ring surrounding the TIG configuration formed by the second annular ring and the outer member of the annular flow ring conduit when the vertically movable susceptor is in the process position.

15. The reaction chamber apparatus of claim 13, wherein a joint between the second annular ring and the lid is curved.

16. The reaction chamber apparatus of claim 13, wherein a joint between the second annular ring and the lid is filleted.

17. The reaction chamber apparatus of claim 13, wherein the TIG configuration comprises a staircase.

18. The reaction chamber apparatus of claim 17, wherein the second annular ring is an inner lid ring and further comprising an outer lid ring surrounding the TIG configuration formed by the second annular ring and the outer member of the annular flow ring conduit when the vertically movable susceptor is in the process position.

19. The reaction chamber apparatus of claim 18, wherein a joint between the second annular ring and the lid is curved.

20. The reaction chamber apparatus of claim 13, wherein a joint between the second annular ring and the lid is filleted.
